(19) United States
(12) Patent Application Publication
(10) Pub. No.: US 2026/0136740 A1
(43) Pub. Date: May 14, 2026

(54) LIGHT-EMITTING DIODE AND LIGHT-EMITTING DIODE DISPLAY DEVICE

(71) Applicant: LG Display Co., Ltd., Seoul (KR)

(72) Inventors: Su-Min LEE, Paju-si (KR); Byung-Hyun LEE, Paju-si (KR); Dae-Young SEO, Paju-si (KR); Tae-Yong KIM, Paju-si (KR); Young-In JANG, Paju-si (KR)

(73) Assignee: LG Display Co., Ltd., Seoul (KR)

(21) Appl. No.: 19/321,938

(22) Filed: Sep. 8, 2025

(30) Foreign Application Priority Data
Nov. 11, 2024 (KR) 10-2024-0159461

(51) Int. Cl. H10H 29/80; H10H 29/49

(52) U.S. Cl. CPC H10H 29/8321; H10H 29/49

(57) ABSTRACT

A light-emitting diode and a light-emitting diode display device are discussed. The light-emitting diode in some examples includes a semiconductor layer, a first element electrode on the semiconductor layer, a second element electrode on the semiconductor layer, a first auxiliary electrode connected to the first element electrode and located on one side surface of the light-emitting diode, a first protection layer on the first element electrode and the second element electrode, and a second protection layer on the first auxiliary electrode and the first protection layer.

### CROSS-REFERENCE TO RELATED APPLICATION

The present application claims priority to Korean Patent Application No. 10-2024-0159461, filed in the Republic of Korea on Nov. 11, 2024, the entire contents of which are hereby expressly incorporated by reference into the present application.

### BACKGROUND

### Technical Field

The present disclosure relates to a display device, and more particularly, to a light-emitting diode display device.

### Discussion of the Related Art

As the information society progresses, a demand for different types of display devices increases, and flat panel display devices (FPD) such as liquid crystal display devices and light-emitting diode display devices have been developed and applied to various fields.

Among the flat panel display devices, light-emitting diode display devices emit light due to the radiative recombination of an exciton. The exciton is formed from an electron and a hole by injecting charges into a light-emitting layer between a cathode for injecting electrons and an anode for injecting holes in a light-emitting diode.

The light-emitting diode display device can offer various advantages and improved properties. For instance, compared to the liquid crystal display device, since the light-emitting diode display device is self-luminous, the light-emitting diode display device has a wide viewing angle. Further, since a backlight unit is not required, the light-emitting diode display device has an ultra-thin thickness and light weight. In addition, the light-emitting diode display device is also advantageous in power consumption.

The light-emitting diode display device can include inorganic-based light-emitting elements and organic-based light-emitting elements. The inorganic-based light-emitting elements have relatively excellent stability, fast response characteristics, and high contrast ratios, and micro light-emitting diodes (micro LEDs or uLED) are widely used as the inorganic-based light-emitting elements for high resolution.

The inorganic-based light-emitting elements are formed on an element substrate and are transferred to an array substrate of a display device. Then, signal electrodes for transmitting signals are formed on the array substrate of the display device. However, since a size of the light-emitting element is relatively very small, a distance between the signal electrodes is very short, so that an electrical short-circuiting can occur between electrodes of the light-emitting element.

### SUMMARY OF THE DISCLOSURE

Accordingly, embodiments of the present disclosure are directed to a light-emitting diode display device that substantially obviates one or more of the problems due to limitations and disadvantages of the related art.

An aspect of the present disclosure is to provide a light-emitting diode display device capable of preventing an electrical short-circuiting between electrodes of a light-emitting diode.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, a light-emitting diode comprises a semiconductor layer; a first element electrode on the semiconductor layer; a second element electrode on the semiconductor layer; a first auxiliary electrode connected to the first element electrode and located on one side surface of the light-emitting diode; a first protection layer on the first element electrode and the second element electrode; and a second protection layer on the first auxiliary electrode and the first protection layer.

According to aspects of the present disclosure, a light-emitting element display device includes a substrate; a light-emitting element disposed on the substrate, the light-emitting element comprising a first element electrode, a second element electrode and an auxiliary electrode, the first element electrode and the second element electrode being spaced apart from each other, and the auxiliary electrode being located on at least one side of the light-emitting element; a first electrode connected to the first element electrode; and a second electrode on the first electrode and connected to the second element electrode, wherein at least one of the first electrode and the second electrode are connected to at least one of the first element electrode and the second element electrode by the auxiliary electrode.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and which are incorporated in and constitute a part of this application, illustrate embodiments of the disclosure and together with the description serve to explain various principles of the disclosure. In the drawings:

FIG. 1 is an example of an equivalent circuit diagram of one sub-pixel of a light-emitting diode display device according to one or more embodiments of the present disclosure;

FIG. 2 is a schematic plan view of a light-emitting diode/element display device according to one or more embodiments of the present disclosure and shows a sub-pixel;

FIG. 3 is a schematic cross-sectional view of a light-emitting diode display device according to one or more embodiments of the present disclosure and shows a cross-section corresponding to areas A1, A2, and A3 of FIG. 2;

FIGS. 4A to 4K are schematic cross-sectional views of a light-emitting diode display device in steps of manufacturing the same according to one or more embodiments of the present disclosure and will be described with reference to FIG. 3 together; and

FIG. 5 is a schematic cross-sectional view of a light-emitting diode display device according to another embodiment of the present disclosure.

### DETAILED DESCRIPTION OF THE EMBODIMENTS

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure.

Further, in the following description of the present disclosure, when a detailed description of a known related art is determined to unnecessarily obscure the gist of the present disclosure, the detailed description thereof will be omitted herein or can be briefly discussed.

When terms such as “including,” “having,” “comprising” and the like mentioned in this disclosure are used, other parts can be added unless the term “only” is used herein.

Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner. For example, the term “in contact with,” as used herein, encompasses both “indirect contact” and “direct contact.” Accordingly, when the phrase “A is in contact with B” is used, it implies that other components can be present between A and B, unless explicitly specified as “A is in direct contact with B.”

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure. Further, the term “can” fully encompasses all the meanings and coverages of the term “may and vice versa.

Features of various embodiments of the present disclosure can be partially or entirely united or combined with each other, technically various interlocking and driving are possible, and each of the embodiments can be independently implemented with respect to each other or implemented together in a related relationship.

Hereinafter, example embodiments of the present disclosure will be described in detail with reference to accompanying drawings. All the components of each display device/apparatus according to all embodiments of the present disclosure are operatively coupled and configured. Further, an example of a light-emitting element is a light-emitting diode but the light-emitting element can be other types.

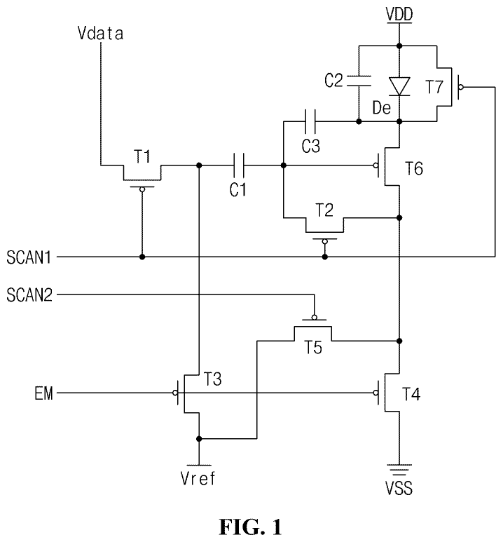

A light-emitting diode display device according to one or more embodiments of the present disclosure can include a plurality of pixels and each pixel can include a plurality of sub-pixels. Each sub-pixel can have a configuration of FIG. 1.

FIG. 1 is an example of an equivalent circuit diagram of one sub-pixel of a light-emitting diode display device (or light-emitting element display device) according to an embodiment of the present disclosure.

Referring to FIG. 1, a sub-pixel of a light-emitting diode display device according to an embodiment of the present disclosure can include first, second, third, fourth, fifth, sixth, and seventh transistors T1, T2, T3, T4, T5, T6, and T7, first, second, and third capacitors C1, C2, and C3, and a light-emitting diode De.

For example, the first, second, third, fourth, fifth, sixth, and seventh transistors T1, T2, T3, T4, T5, T6, and T7 can be p-type transistors. However, embodiments of the present disclosure are not limited thereto. Alternatively, the first, second, third, fourth, fifth, sixth, and seventh transistors T1, T2, T3, T4, T5, T6, and T7 can be n-type transistors or other types of transistors.

The first transistor T1 can be switched according to a first gate signal SCAN1 and can be connected to a data signal Vdata. Specifically, a gate of the first transistor T1 can be connected to the first gate signal SCAN1. A source of the first transistor T1 can be connected to the data signal Vdata. A drain of the first transistor T1 can be connected to one electrode of the first capacitor C1 and a source of the third transistor T3.

The second transistor T2 can be switched according to the first gate signal SCAN1 and can be connected to the sixth transistor T6. Specifically, a gate of the second transistor T2 can be connected to the first gate signal SCAN1. A source of the second transistor T2 can be connected to the other electrode of the first capacitor C1, one electrode of the third capacitor C3, and a gate of the sixth transistor T6. A drain of the second transistor T2 can be connected to a drain of the sixth transistor T6, a source of the fourth transistor T4, and a drain of the fifth transistor T5.

The third transistor T3 can be switched according to an emission signal EM and can be connected to a reference voltage Vref. Specifically, a gate of the third transistor T3 can be connected to the emission signal EM. The source of the third transistor T3 can be connected to the one electrode of the first capacitor C1 and the drain of the first transistor T1. A drain of the third transistor T3 can be connected to the reference voltage Vref and a source of the fifth transistor T5.

The fourth transistor T4 can be switched according to the emission signal EM and can be connected to a low potential voltage VSS. Specifically, a gate of the fourth transistor T4 can be connected to the emission signal EM. The source of the fourth transistor T4 can be connected to the drain of the sixth transistor T6, the drain of the second transistor T2, and the drain of the fifth transistor T5. A drain of the fourth transistor T4 can be connected to the low potential voltage VSS.

The fifth transistor T5 can be switched according to a second gate signal SCAN2 and can be connected to the reference voltage Vref and the sixth transistor T6. Specifically, a gate of the fifth transistor T5 can be connected to the second gate signal SCAN2. The source of the fifth transistor T5 can be connected to the reference voltage Vref and the drain of the third transistor T3. The drain of the fifth transistor T5 can be connected to the drain of the sixth transistor T6, the drain of the second transistor T2, and the drain of the fourth transistor T4.

The sixth transistor T6 can be a driving transistor, can be switched according to a voltage of the one electrode of the third capacitor C3, and can be connected to the light-emitting diode De. Specifically, the gate of the sixth transistor T6 can be connected to the one electrode of the third capacitor C3, the other electrode of the first capacitor C1, and the source of the second transistor T2. The source of the sixth transistor T6 can be connected to a cathode of the light-emitting diode De, the other electrode of the second capacitor C2, the other electrode of the third capacitor C3, and a drain of the seventh transistor T7. The drain of the sixth transistor T6 can be connected to the drain of the second transistor T2, the source of the fourth transistor T4, and the drain of the fifth transistor T5.

The seventh transistor T7 can be switched according to the first gate signal SCAN1 and can be connected to a high potential voltage VDD and the light-emitting diode De. Specifically, a gate of the seventh transistor T7 can be connected to the first gate signal SCAN1. The source of the seventh transistor T7 can be connected to an anode of the light-emitting diode De, the high potential voltage VDD, and one electrode of the second capacitor C2. The drain of the seventh transistor T7 can be connected to the cathode of the light-emitting diode De, the source of the sixth transistor T6, the other electrode of the second capacitor C2, and the other electrode of the third capacitor C3.

The first, second, and third capacitors C1, C2, and C3 can be storage capacitors and can store the data signal Vdata and the threshold voltage Vth. The third capacitor C3 can be disposed between the first and second capacitors C1 and C2. In addition, the first capacitor C1 can be connected between the drain of the first transistor T1 and the gate of the sixth transistor T6. The second capacitor C2 can be connected between the high potential voltage VDD and the source of the sixth transistor T6 and can be connected to the light-emitting diode De in parallel. The third capacitor C3 can be connected between the gate and the source of the sixth transistor T6.

The light-emitting diode De can be connected between the sixth transistor T6 and the high potential voltage VDD and can emit light with luminance proportional to a current of the sixth transistor T6. Specifically, the anode of the light-emitting diode De can be connected to the high potential voltage VDD, the one electrode of the second capacitor C2, and the source of the seventh transistor T7. The cathode of the light-emitting diode De can be connected to the source of the sixth transistor T6, the other electrode of the second capacitor C2, the other electrode of the third capacitor C3, and the drain of the seventh transistor T7.

In the embodiment of the present disclosure of FIG. 1, as an example, each sub-pixel has a 7T3C structure including seven transistors and three capacitors, but embodiments of the present disclosure are not limited thereto. In other embodiments, each sub-pixel can have one of 2T1C, 3T1C, 4T1C, 5T1C, 3T2C, 4T2C, 5T2C, 6T2C, 7T1C, 7T2C, 8T1C, and 8T2C structures.

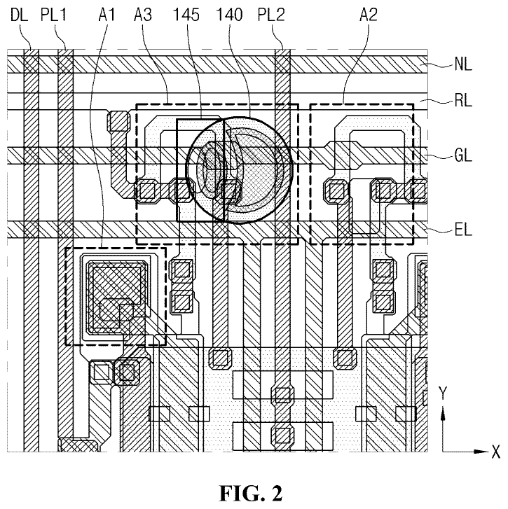

The planar configuration of the light-emitting diode display device according to the embodiment of the present disclosure will be described with reference to FIG. 2.

FIG. 2 is a schematic plan view of a light-emitting diode display device (or light-emitting element display device) according to the embodiment of the present disclosure and shows a sub-pixel.

Referring to FIG. 2, a gate line GL, an emission line EL, and a reference line RL can extend in a first direction X and can be spaced apart from each other in a second direction Y. In this case, the gate line GL can be disposed between the emission line EL and the reference line RL, but embodiments of the present disclosure are not limited thereto.

The gate line GL can transmit the first gate signal SCAN1 or the second gate signal SCAN2 of FIG. 1. The emission line EL can transmit the emission signal EM of FIG. 1. The reference line RL can transmit the reference voltage Vref of FIG. 1.

In addition, a driving line NL can be further provided to extend in the first direction X. The driving line NL can be a part of a gate driving portion for generating signals that are applied to the gate line GL and/or the emission line EL. However, embodiments of the present disclosure are not limited thereto. In other embodiments, the driving line NL can be omitted.

A data line DL, a first power line PL1, and a second power line PL2 can extend in the second direction Y and can be spaced apart from each other in the first direction X. In this case, the first power line PL1 can be disposed between the data line DL and the second power line PL2, but embodiments of the present disclosure are not limited thereto.

The data line DL can transmit the data signal Vdata of FIG. 1, the first power line PL1 can transmit the high potential voltage VDD of FIG. 1, and the second power line PL2 can transmit the low potential voltage VSS of FIG. 1.

The first, second, third, fourth, fifth, sixth, and seventh transistors T1, T2, T3, T4, T5, T6, and T7 and the first, second, and third capacitors C1, C2, and C3 of FIG. 1 can be selectively connected to the lines GL, EL, RL, DL, PL1, and PL2.

In addition, a light-emitting element 140 can be provided substantially between the first power line PL1 and the second power line PL2. However, embodiments of the present disclosure are not limited thereto, and the location of the light-emitting element 140 can vary.

Here, the light-emitting element 140 can further include an auxiliary electrode 145 on a side thereof. Accordingly, in the light-emitting diode display device according to the embodiment of the present disclosure, an electrode of the light-emitting element 140 can be connected to a signal electrode of an array substrate through the auxiliary electrode 145, thereby preventing an electrical short-circuiting between two electrodes of the light-emitting element 140.

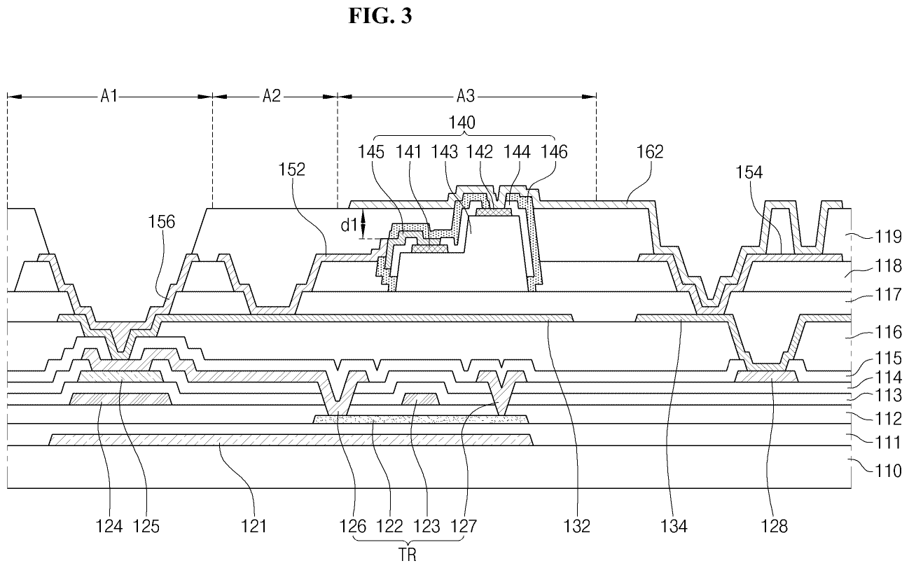

A cross-sectional structure of the light-emitting diode display device according to the embodiment of the present disclosure will be described in detail with reference to FIG. 3.

FIG. 3 is a schematic cross-sectional view of a light-emitting diode display device (or light-emitting element display device) according to the embodiment of the present disclosure and shows a cross-section corresponding to areas A1, A2, and A3 of FIG. 2.

Referring to FIG. 3, the light-emitting diode display device according to the embodiment of the present disclosure can include a thin film transistor TR and the light-emitting element 140 over a substrate 110. A first element electrode 141 of the light-emitting element 140 can be connected to the thin film transistor TR, and a second element electrode 142 of the light-emitting element 140 can be connected to a power line 128.

Specifically, a light-shielding layer 121 can be provided on the substrate 110. The substrate 110 can be a glass substrate or a plastic substrate. For example, polyimide can be used for the plastic substrate, and the plastic substrate can have a stacked structure including at least one polyimide layer and at least one inorganic layer. However, embodiments of the present disclosure are not limited thereto.

The light-shielding layer 121 can be formed of a conductive material such as metal. For example, the light-shielding layer 121 can be formed of one or more of: aluminum (Al), copper (Cu), molybdenum (Mo), titanium (Ti), chromium (Cr), nickel (Ni), tungsten (W), and an alloy thereof. The light-shielding layer 121 can have a single-layered structure or a multiple-layered structure.

A buffer layer 111 can be provided on the light-shielding layer 121. The buffer layer 111 can be disposed substantially all over the substrate 110. The buffer layer 111 can be formed as a single layer or multiple layers of an inorganic insulating material. The inorganic insulating material of the buffer layer 111 can include silicon nitride (SiNₓ), silicon oxide (SiOₓ), or silicon oxynitride (SiON).

An active layer 122 can be provided on the buffer layer 111. The active layer 122 can overlap the light-shielding layer 121, and the light-shielding layer 121 can block light incident on the active layer 122 and prevent the active layer 122 from deteriorating due to the light.

The active layer 122 can include a channel region at its central part and source and drain regions at both sides of the channel region.

The active layer 122 can be formed of an oxide semiconductor material. Alternatively, the active layer 122 can be formed of polycrystalline silicon, and in this case, both ends of the active layer 122 can be doped with impurities.

A gate insulation layer 112 can be provided on the active layer 122 and the buffer layer 111. The gate insulation layer 112 can be disposed substantially all over the substrate 110. The gate insulation layer 112 can be formed as a single layer or multiple layers of an inorganic insulating material. The inorganic insulating material of the gate insulation layer 112 can include silicon nitride (SiNₓ), silicon oxide (SiOₓ), or silicon oxynitride (SiON).

A gate electrode 123 and a first capacitor electrode 124 can be formed on the gate insulation layer 112. The gate electrode 123 can overlap the active layer 122 and can be disposed to correspond to the central part of the active layer 122. Accordingly, the gate electrode 123 can also overlap the light-shielding layer 121.

The first capacitor electrode 124 can be spaced apart from the active layer 122 and can overlap the light-shielding layer 121.

The gate electrode 123 and the first capacitor electrode 124 can be formed of a conductive material such as metal. For example, the gate electrode 123 and the first capacitor electrode 124 can be formed of one or more of: aluminum (Al), copper (Cu), molybdenum (Mo), titanium (Ti), chromium (Cr), nickel (Ni), tungsten (W), and an alloy thereof. The gate electrode 123 and the first capacitor electrode 124 can have a single-layered structure or a multiple-layered structure.

A first interlayer insulation layer 113 can be provided on the gate electrode 123 and the first capacitor electrode 124. The first interlayer insulation layer 113 can be disposed substantially all over the substrate 110. The first interlayer insulation layer 113 can be formed as a single layer or multiple layers of an inorganic insulating material. The inorganic insulating material of the first interlayer insulation layer 113 can include silicon nitride (SiNₓ), silicon oxide (SiOₓ), or silicon oxynitride (SiON).

A second capacitor electrode 125 can be provided on the first interlayer insulation layer 113. The second capacitor electrode 125 can overlap the first capacitor electrode 124 to thereby form a storage capacitor. The second capacitor electrode 125 can also overlap the light-shielding layer 121.

The second capacitor electrode 125 can be formed of a conductive material such as metal. For example, the second capacitor electrode 125 can be formed of one or more of: aluminum (Al), copper (Cu), molybdenum (Mo), titanium (Ti), chromium (Cr), nickel (Ni), tungsten (W), and an alloy thereof. The second capacitor electrode 125 can have a single-layered structure or a multiple-layered structure.

A second interlayer insulation layer 114 can be provided on the second capacitor electrode 125. The second interlayer insulation layer 114 can be disposed substantially all over the substrate 110. The second interlayer insulation layer 114 can be formed as a single layer or multiple layers of an inorganic insulating material. The inorganic insulating material of the second interlayer insulation layer 114 can include silicon nitride (SiNₓ), silicon oxide (SiOₓ), or silicon oxynitride (SiON).

A source electrode 126, a drain electrode 127, and a power line 128 can be provided on the second interlayer insulation layer 114.

The source electrode 126 and the drain electrode 127 can be spaced apart from each other with the gate electrode 123 positioned therebetween and can be in contact with both ends of the active layer 122 through contact holes provided in the first and second interlayer insulation layers 113 and 114 and the gate insulation layer 112.

In addition, the source electrode 126 can extend to overlap the first and second capacitor electrodes 124 and 125. The source electrode 126 can be in contact with the second capacitor electrode 125 through a contact hole provided in the second interlayer insulation layer 114.

The active layer 122, the gate electrode 123, the source electrode 126, and the drain electrode 127 can constitute a thin film transistor TR. The thin film transistor TR can be a driving transistor. For example, the thin film transistor TR can be the sixth transistor T6 of FIG. 1. However, embodiments of the present disclosure are not limited thereto.

Meanwhile, the power line 128 can be spaced apart from the thin film transistor TR and the light-shielding layer 121. The power line 128 can transmit the high potential voltage VDD.

The source electrode 126, the drain electrode 127, and the power line 128 can be formed of a conductive material such as metal. For example, the source electrode 126, the drain electrode 127, and the power line 128 can be formed of one or more of: aluminum (Al), copper (Cu), molybdenum (Mo), titanium (Ti), chromium (Cr), nickel (Ni), tungsten (W), and an alloy thereof. The source electrode 126, the drain electrode 127, and the power line 128 can have a single-layered structure or a multiple-layered structure.

A passivation layer 115 can be provided on the source electrode 126, the drain electrode 127, and the power line 128. The passivation layer 115 can be disposed substantially all over the substrate 110. The passivation layer 115 can be formed as a single layer or multiple layers of an inorganic insulating material. The inorganic insulating material of the passivation layer 115 can include silicon nitride (SiNₓ), silicon oxide (SiOₓ), or silicon oxynitride (SiON).

A first planarization layer 116 can be provided on the passivation layer 115. The first planarization layer 116 can be disposed substantially all over the substrate 110.

The first planarization layer 116 can eliminate a step difference due to the layers thereunder and can have a substantially flat top surface. The first planarization layer 116 can be formed of an organic insulating material such as photosensitive acrylic polymer (photo acryl).

A reflection electrode 132 and a first connection electrode 134 can be provided on the first planarization layer 116. The reflection electrode 132 can overlap the thin film transistor TR and the first and second capacitor electrodes 124 and 125. The reflection electrode 132 can be in contact with the source electrode 126 over the first and second capacitor electrodes 124 and 125 through a contact hole provided in the passivation layer 115 and the first planarization layer 116. Accordingly, the reflection electrode 132 can be electrically connected to the second capacitor electrode 125 through the source electrode 126.

The first connection electrode 134 can overlap the power line 128 and can be in contact with the power line 128 through a contact hole provided in the passivation layer 115 and the first planarization layer 116.

The reflection electrode 132 and the first connection electrode 134 can be formed of a metal having relatively high reflectance. For example, the reflection electrode 132 and the first connection electrode 134 can be formed of aluminum (Al), silver (Ag), or chromium (Cr).

An adhesive layer 117 can be provided on the reflection electrode 132 and the first connection electrode 134. The adhesive layer 117 can be disposed substantially all over the substrate 110 and can fix the light-emitting element 140 that is transferred thereon.

The adhesive layer 117 can have a substantially flat top surface. For example, the first planarization layer 116 can be formed of an organic insulating material such as photosensitive acrylic polymer (photo acryl). Alternatively, the adhesive layer 117 can be formed of one of a polyimide (PI) resin, an epoxy resin, a urethane resin, and a polydimethylsiloxane (PDMS) resin.

The light-emitting element 140 can be provided on the adhesive layer 117. The light-emitting element 140 can overlap the reflection electrode 132. In addition, the light-emitting element 140 can also overlap the thin film transistor TR and the light-shielding layer 121.

The light-emitting element 140 can be provided in the form of a micro light-emitting diode chip (micro LED chip or uLED chip) including an n-electrode, an n-type layer, an active layer, a p-type layer, and a p-electrode. The light-emitting element 140 can have a lateral structure in which the n-electrode and the p-electrode are provided on the same side (for example, a second side opposite to a first side facing the substrate 110) and light is emitted through the second side provided with the n-electrode and the p-electrode (for example, the second side opposite to the first side facing the substrate 110).

However, embodiments of the present disclosure are not limited thereto. The light-emitting element 140 can have a flip-chip structure in which the n-electrode and the p-electrode are provided on the same side (for example, the first side facing the substrate 110) and light is emitted through the second side opposite to the first side provided with the n-electrode and the p-electrode. Alternatively, the light-emitting element 140 can have a vertical structure in which the n-electrode and the p-electrode are provided on opposite sides (for example, a first side facing the substrate 110 and a second side opposite to the first side), respectively.

The light-emitting element 140 can include the first element electrode 141, the second element electrode 142, a semiconductor layer 143, a first protection layer 144, an auxiliary electrode 145, and a second protection layer 146.

The first element electrode 141 and the second element electrode 142 can be provided on the semiconductor layer 143 and can be spaced from each other. The semiconductor layer 143 can include an n-type layer, an active layer, and a p-type layer.

The semiconductor layer 143 can have a step difference at its top surface. The first element electrode 141 and the second element electrode 142 can be disposed at different heights. For example, the second element electrode 142 can be disposed higher than the first element electrode 141.

Here, the first element electrode 141 can be an n-electrode, and the second element electrode 142 can be a p-electrode. The first element electrode 141 can be a cathode, and the second element electrode 142 can be an anode.

However, embodiments of the present disclosure are not limited thereto. Alternatively, in other embodiments, the first element electrode 141 can be a p-electrode, and the second element electrode 142 can be an n-electrode. In this case, the first element electrode 141 can be an anode, and the second element electrode 142 can be a cathode.

The first protection layer 144 can be provided on the first element electrode 141, the second element electrode 142, and the semiconductor layer 143. The first protection layer 144 can cover and protect the first element electrode 141, the second element electrode 142, and the semiconductor layer 143 and can partially expose top surfaces of the first element electrode 141 and the second element electrode 142.

The auxiliary electrode 145 can be provided on the first protection layer 144. The auxiliary electrode 145 can correspond to top and side surfaces of the semiconductor layer 143. The auxiliary electrode 145 can overlap the first element electrode 141 and can be spaced apart from the second element electrode 142. The auxiliary electrode 145 can be in contact with the top surface of the first element electrode 141 exposed through a contact hole provided in the first protection layer 144.

The second protection layer 146 can be provided on the auxiliary electrode 145. The second protection layer 146 can cover and protect the auxiliary electrode 145 and can be in contact with the first protection layer 144.

The second protection layer 146 can partially expose the auxiliary electrode 145 and the second element electrode 142. In this case, the second protection layer 146 can cover and be in contact with the auxiliary electrode 145 corresponding to the top surface of the semiconductor layer 143 and can expose the auxiliary electrode 145 corresponding to the side surface of the semiconductor layer 143. In addition, the second protection layer 146 can expose the top surface of the second element electrode 142 exposed through the contact hole of the first protection layer 144.

Next, a second planarization layer 118 can be provided on the light-emitting element 140 and the adhesive layer 117. The second planarization layer 118 can be disposed substantially all over the substrate 110. The second planarization layer 118 can be formed of an organic insulating material such as photosensitive acrylic polymer (photo acryl). The second planarization layer 118 can have a substantially flat top surface.

A thickness of the second planarization layer 118 can be smaller than a thickness of the light-emitting element 140. The second planarization layer 118 can expose the auxiliary electrode 145 and the second element electrode 142. In this case, the second planarization layer 118 can expose the auxiliary electrode 145 corresponding to the side surface of the semiconductor layer 143.

A first electrode 152, a second connection electrode 154, and a contact electrode 156 can be provided on the second planarization layer 118.

The first electrode 152 can overlap the light-emitting element 140 and can be in connected to the auxiliary electrode 145 of the light-emitting element 140. In this case, the first electrode 152 can be in contact with the auxiliary electrode 145 exposed to correspond to the side surface of the semiconductor layer 143 and may not be formed on the auxiliary electrode 145 corresponding to the top surface of the semiconductor layer 143.

In addition, the first electrode 152 can overlap the reflection electrode 132 and can be in contact with the reflection electrode 132 through a contact hole provided in the adhesive layer 117 and the second planarization layer 118.

Accordingly, the first electrode 152 can be electrically connected to the source electrode 126 of the thin film transistor TR and the second capacitor electrode 125 through the reflection electrode 132. The first element electrode 141 of the light-emitting element 140 can be electrically connected to the source electrode 126 of the thin film transistor TR and the second capacitor electrode 125 through auxiliary electrode 145, the first electrode 152, and the reflection electrode 132.

The second connection electrode 154 can overlap the first connection electrode 134 and can be in contact with the first connection electrode 134 through a contact hole provided in the adhesive layer 117 and the second planarization layer 118. Accordingly, the second connection electrode 154 can be electrically connected to the power line 128 through the first connection electrode 134.

Meanwhile, the contact electrode 156 can overlap the reflection electrode 132, the source electrode 126, and the first and second capacitor electrodes 124 and 125. The contact electrode 156 can be in contact with the reflection electrode 132 through a contact hole provided in the adhesive layer 117 and the second planarization layer 118.

Accordingly, the contact electrode 156 can be electrically connected to the source electrode 126 of the thin film transistor TR and the second capacitor electrode 125 through the reflection electrode 132. In addition, the contact electrode 156 can be electrically connected to first electrode 152, and the auxiliary electrode 145 and the first element electrode 141 of the light-emitting element 140 through the reflection electrode 132.

The first electrode 152, the second connection electrode 154, and the contact electrode 156 can be formed of a transparent conductive material such as indium tin oxide (ITO) or indium zinc oxide (IZO). Alternatively, the first electrode 152, the second connection electrode 154, and the contact electrode 156 can be formed of a metal such as aluminum (Al), copper (Cu), molybdenum (Mo), titanium (Ti), chromium (Cr), nickel (Ni), tungsten (W), or an alloy thereof.

A third planarization layer 119 can be provided on the first electrode 152, the second connection electrode 154, and the contact electrode 156. The third planarization layer 119 can be disposed substantially all over the substrate 110. The third planarization layer 119 can be formed of an organic insulating material such as photosensitive acrylic polymer (photo acryl). The third planarization layer 119 can have a substantially flat top surface.

The third planarization layer 119 can cover the light-emitting element 140 and the first electrode 152 and can expose a part of the light-emitting element 140. Specifically, the third planarization layer 119 can cover the first element electrode 141 and the auxiliary electrode 145 of the light-emitting element 140 and can expose the second element electrode 142 of the light-emitting element 140.

In addition, the third planarization layer 119 can partially expose the second connection electrode 154 and the contact electrode 156.

Next, a second electrode 162 can be provided on the third planarization layer 119. The second electrode 162 can overlap the light-emitting element 140, the first electrode 152, and the second connection electrode 154 and can be spaced apart from the contact electrode 156.

Specifically, the second electrode 162 can overlap the first element electrode 141, the second element electrode 142, and the auxiliary electrode 145 of the light-emitting element 140. The second electrode 162 can be in contact with the exposed second element electrode 142. In addition, the second electrode 162 can also overlap a part of the first electrode 152.

The second electrode 162 can extend to overlap the second connection electrode 154. The second electrode 162 can be in contact with the second connection electrode 154 through a contact hole provided in the third planarization layer 119. Accordingly, the second electrode 162 can be electrically connected to the first connection electrode 134 through the second connection electrode 154. The second element electrode 142 of the light-emitting element 140 can be electrically connected to the power line 128 through the second electrode 162 and the first and second connection electrodes 134 and 154.

In this case, the second electrode 162 can be in contact with the second connection electrode 154 through at least two contact holes, thereby improving contact properties between the second electrode 162 and the second connection electrode 154.

The second electrode 162 can be formed of a transparent conductive material such as indium tin oxide (ITO) or indium zinc oxide (IZO). Alternatively, the second electrode 162 can be formed of a metal such as aluminum (Al), copper (Cu), molybdenum (Mo), titanium (Ti), chromium (Cr), nickel (Ni), tungsten (W), or an alloy thereof.

As such, in the light-emitting diode display device according to the embodiment of the present disclosure, by connecting the first electrode 152 to the side surface of the light-emitting element 140 and connecting the second electrode 162 to the top surface of the light-emitting element 140, a distance d1 between the first electrode 152 and the second electrode 162 can be increased.

For example, the light-emitting element 140 can include the auxiliary electrode 145 contacting the first element electrode 141. The auxiliary electrode 145 can be provided on the side surface of the semiconductor layer 143 and can be exposed to be connected to the first electrode 162. Accordingly, compared to a light-emitting diode display device including a light-emitting element without an auxiliary electrode, since the distance d1 between the first electrode 152 and the second electrode 162 can be increased, it is possible to prevent an electrical short-circuiting problem between the first and second element electrodes 141 and 142 due to the contact between the first electrode 152 and the second electrode 162.

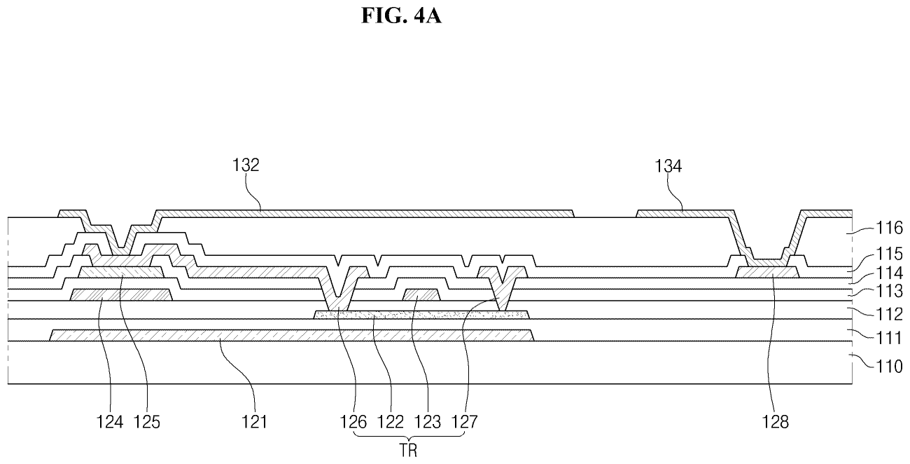

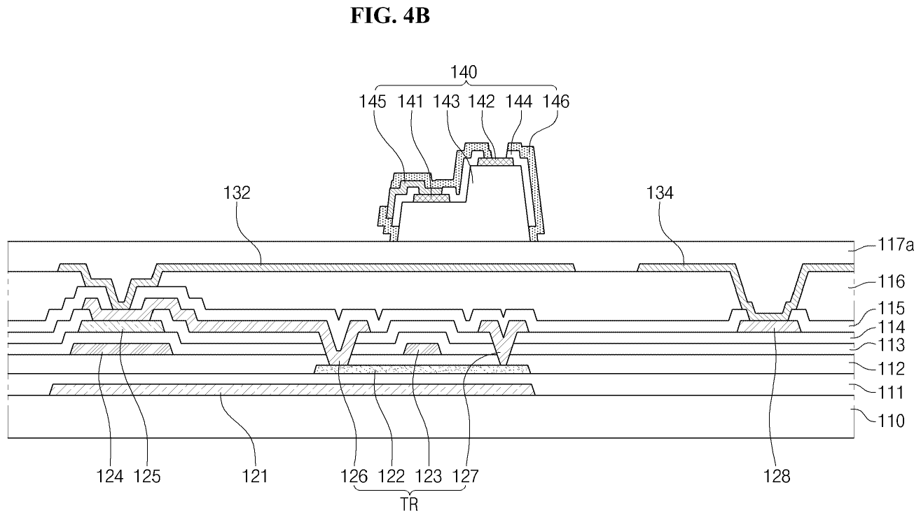

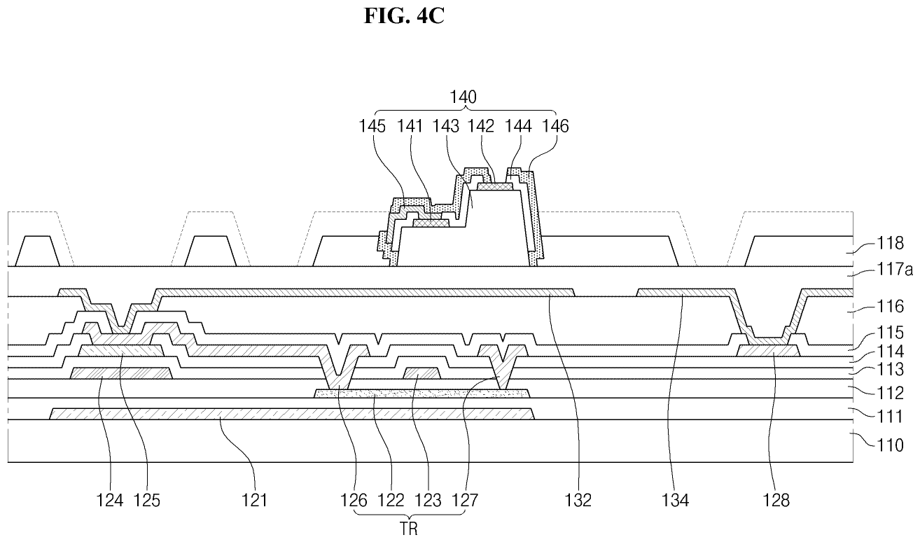

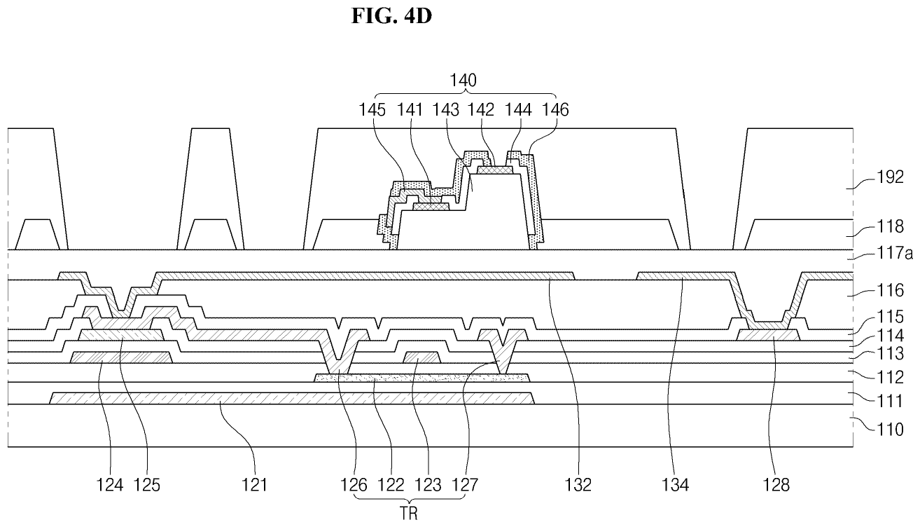

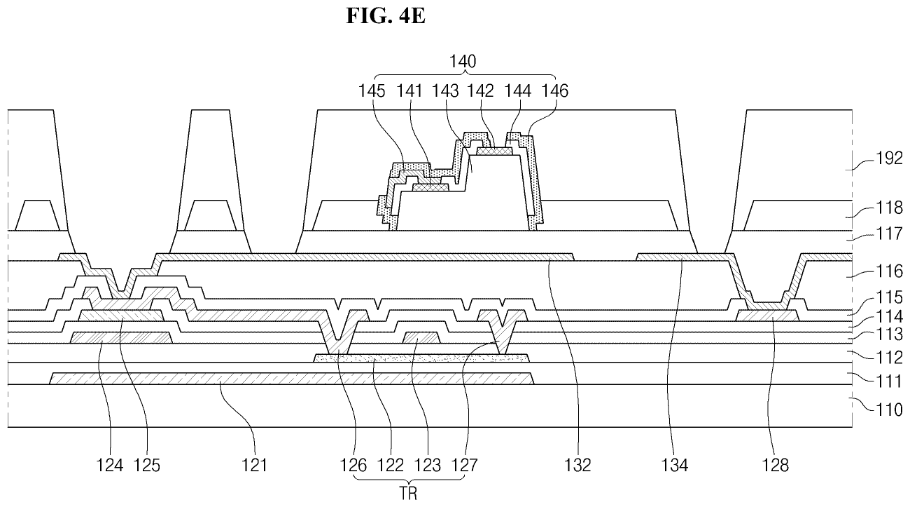

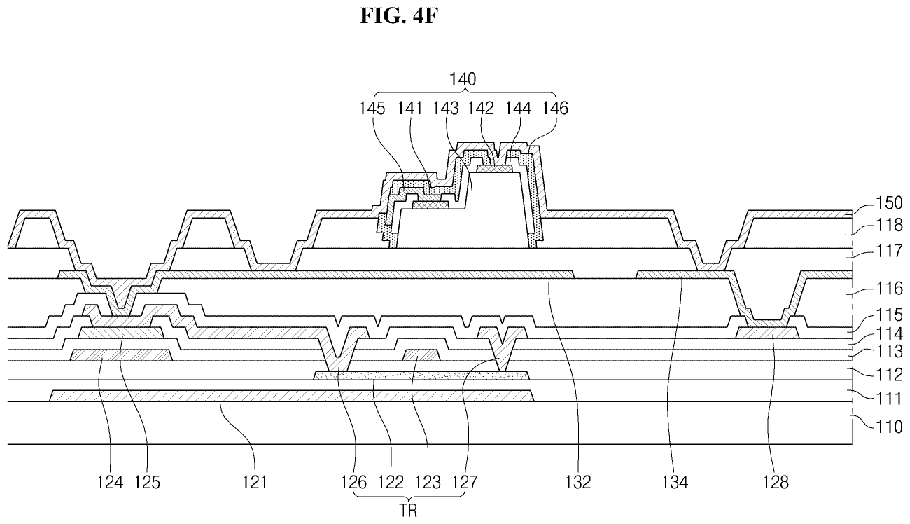

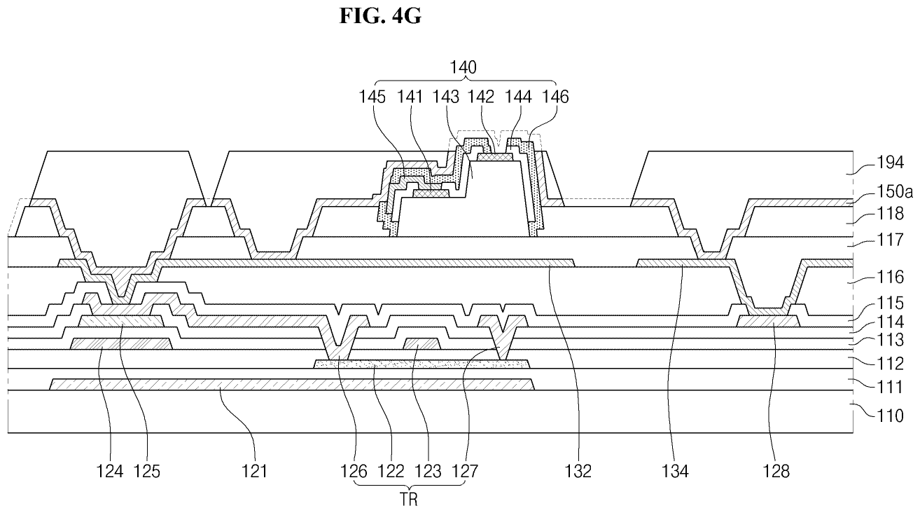

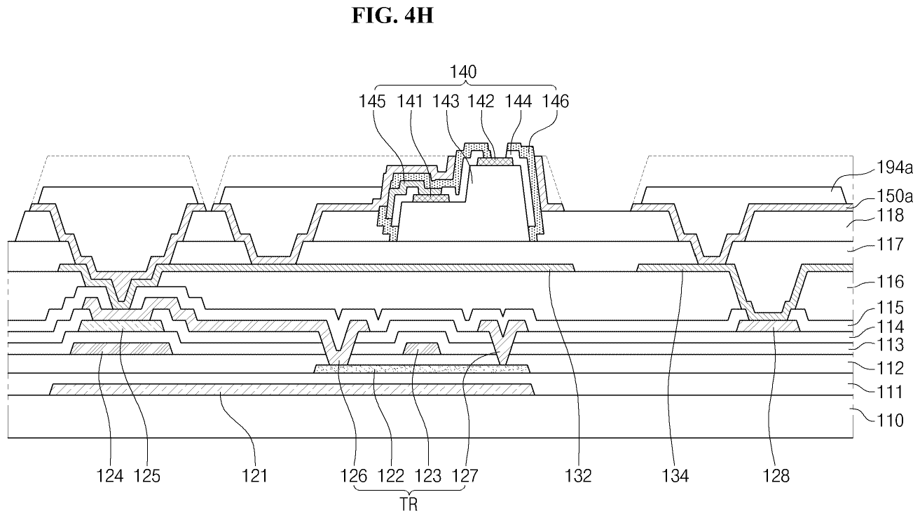

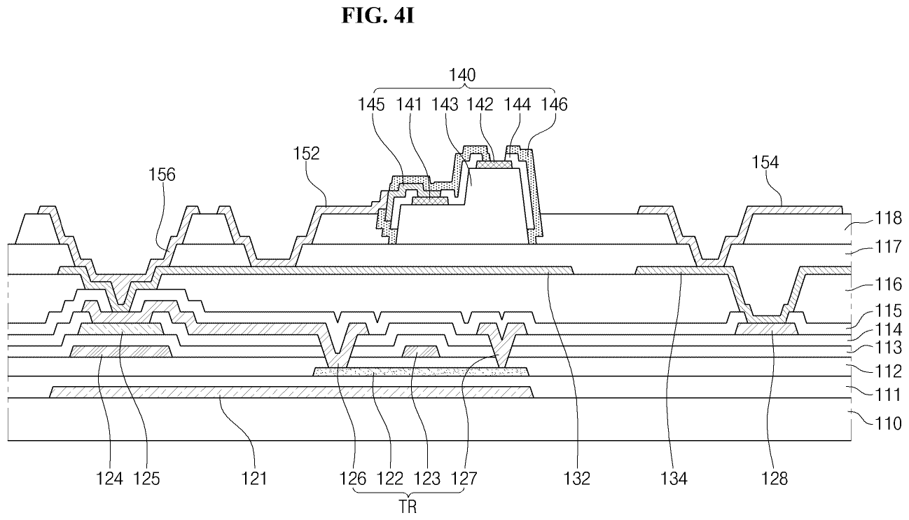

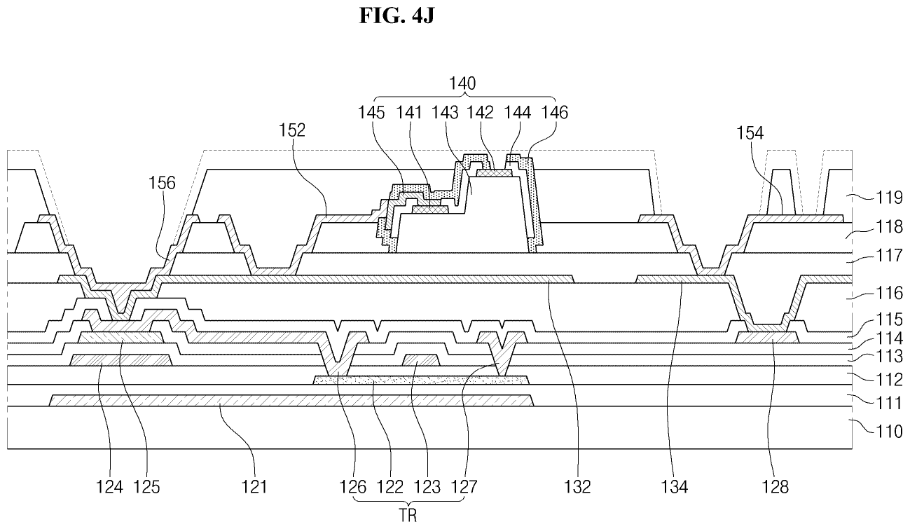

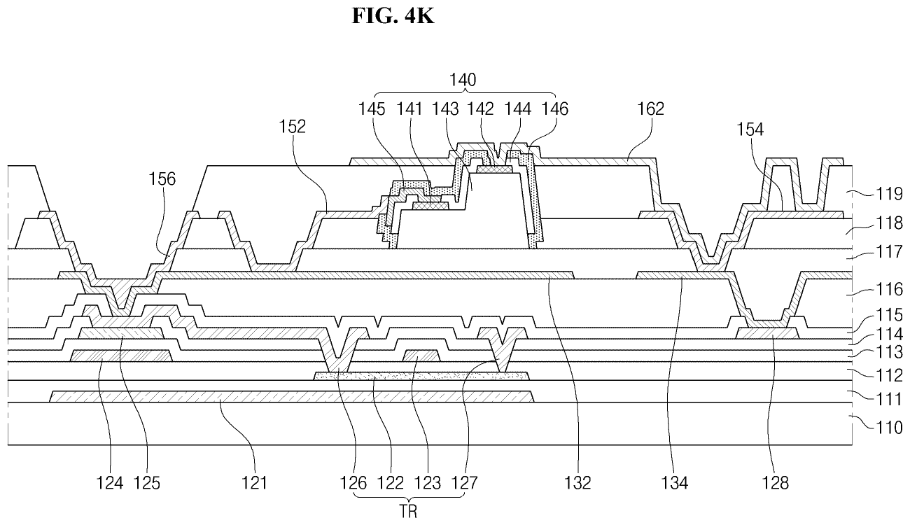

A method of manufacturing the light-emitting diode display device according to the embodiment of the present disclosure including the light-emitting element 140 with the auxiliary electrode 145 will be described with reference to FIGS. 4A to 4K.

FIGS. 4A to 4K are schematic cross-sectional views of a light-emitting diode display device (or light-emitting element display device) in steps of manufacturing the same according to the embodiment of the present disclosure and will be described with reference to FIG. 3 together.

Referring to FIG. 4A, the light-shielding layer 121 can be formed on the substrate 110 by depositing a conductive material and then patterning it through a photolithography process. The buffer layer 111 can be formed on the light-shielding layer 121 by depositing an inorganic insulating material substantially all over the substrate 110. The active layer 122 can be formed on the buffer layer 111 by depositing a semiconductor material and then patterning it through a photolithography process.

Next, the gate insulation layer 112 can be formed on the active layer 122 by depositing an inorganic insulating material substantially all over the substrate 110. The gate electrode 123 and the first capacitor electrode 124 can be formed on the gate insulation layer 112 by depositing a conductive material and then patterning it through a photolithography process.

Next, the first interlayer insulation layer 113 can be formed on the gate electrode 123, the first capacitor electrode 124, and the gate insulation layer 112 by depositing an inorganic insulating material substantially all over the substrate 110. The second capacitor electrode 125 can be formed on the first interlayer insulation layer 113 by depositing a conductive material and then patterning it through a photolithography process.

Then, the second interlayer insulation layer 114 can be formed on the second capacitor electrode 125 and the first interlayer insulation layer 113 by depositing an inorganic insulating material substantially all over the substrate 110, and can be patterned through a photolithography process, thereby forming the contact hole exposing the second capacitor electrode 125. In addition, the first interlayer insulation layer 113 and the gate insulation layer 112 can also be patterned together with the second interlayer insulation layer 114, thereby forming the contact holes exposing the active layer 122.

Next, the source electrode 126, the drain electrode 127, and the power line 128 can be formed on the second interlayer insulation layer 114 by depositing a conductive material and then patterning it through a photolithography process.

The source electrode 126 and the drain electrode 127 can be in contact with the both ends of the active layer 122 through the contact holes provided in the first and second interlayer insulation layers 113 and 114 and the gate insulation layer 112. The active layer 122, the gate electrode 123, the source electrode 126, and the drain electrode 127 can constitute a thin film transistor TR.

In addition, the source electrode 126 can be in contact with the second capacitor electrode 125 through the contact hole provided in the second interlayer insulation layer 114.

Next, the passivation layer 115 can be formed on the source electrode 126, the drain electrode 127, and the power line 128 by depositing an inorganic insulating material substantially all over the substrate 110, and the first planarization layer 116 can be formed on the passivation layer 115 by applying an organic insulating material substantially all over the substrate 110. Then, the first planarization layer 116 and the passivation layer 115 can be patterned through a photolithography process, thereby forming the contact holes exposing the source electrode 126 and the power line 128.

Next, the reflection electrode 132 and the first connection electrode 134 can be formed on the first planarization layer 116 by depositing a conductive material and then patterning it through a photolithography process. The reflection electrode 132 can be in contact with the source electrode 126 through the contact hole provided in the passivation layer 115 and the first planarization layer 116 and the first connection electrode 134 can be in contact with the power line 128 through the contact hole provided in the passivation layer 115 and the first planarization layer 116.

Next, referring to FIG. 4B, an adhesive material layer 117a can be formed on the first planarization layer 117 provided with the reflection electrode 132 and the first connection electrode 134 thereon, and the light-emitting element 140 can be transferred onto the adhesive material layer 117a.

Here, the light-emitting element 140 can include the first element electrode 141, the second element electrode 142, the semiconductor layer 143, the first protection layer 144, the auxiliary electrode 145, and the second protection layer 146.

The light-emitting element 140 can be transferred on the adhesive material layer 117a by self-assembling a light-emitting element 140a without the auxiliary electrode 145 on an assembly substrate, forming the auxiliary electrode 145 and the second protection layer 146, and transferring the light-emitting element 140 with the auxiliary electrode 145 from the assembly substrate onto the substrate 110 provided with the adhesive material layer 117a using a donor substrate.

Next, referring to FIG. 4C, the second planarization layer 118 can be formed on the light-emitting element 140 and the adhesive material layer 117a by applying an organic insulating material substantially all over the substrate 110, and can be patterned through a photolithography process, thereby selectively exposing a top surface of the adhesive material layer 117a corresponding to the reflection electrode 132 and the first connection electrode 134. In this case, the second planarization layer 118 can have a smaller thickness than the light-emitting element 140. Accordingly, the second planarization layer 118 can expose the second element electrode 142 and can cover the auxiliary electrode 145 corresponding to the side surface of the semiconductor layer 143.

Then, the second planarization layer 118 can be partially removed through an ashing process. Accordingly, the thickness of the second planarization layer 118 can be decreased, thereby exposing the auxiliary electrode 145 corresponding to the side surface of the semiconductor layer 143. In this case, a width of the second planarization layer 118 can also be decreased through the ashing process together with the thickness of the second planarization layer 118.

Next, referring to FIG. 4D, a first photoresist pattern 192 can be formed on the light-emitting element 140 and the second planarization layer 118 through a photolithography process where photoresist is applied, exposed to light, and developed. The first photoresist pattern 192 can cover the light-emitting element 140 and the second planarization layer 118 and can expose the top surface of the adhesive material layer 117a corresponding to the reflection electrode 132 and the first connection electrode 134.

In this case, a width of the first photoresist pattern 192 can be greater than a width of the second planarization layer 118, and a distance between adjacent portions of the first photoresist pattern 192 can be smaller than a distance between adjacent portions of the second planarization layer 118.

Next, referring to FIG. 4E, the adhesive material layer 117a can be selectively removed using the first photoresist pattern 192 as an etching mask, thereby forming the adhesive layer 117 having the contact holes that expose the reflection electrode 132 and the first connection electrode 134. In this case, the adhesive material layer 117a can be removed through a dry etching process. A width of the adhesive layer 117 can be greater than the width of the second planarization layer 118, and a distance between adjacent portions of the adhesive layer 117 can be smaller than the distance between the adjacent portions of the second planarization layer 118.

Then, the first photoresist pattern 192 can be stripped and removed.

Next, referring to FIG. 4F, a conductive material layer 150 can be formed on the light-emitting element 140 and the second planarization layer 118 by depositing a conductive material substantially all over the substrate 110.

The conductive material layer 150 can be in contact with the top and side surfaces of the light-emitting element 140, the top and side surfaces of the second planarization layer 118, and the top and side surfaces of the adhesive layer 117. In addition, the conductive material layer 150 can be in contact with the reflection electrode 132 and the first connection electrode 134 through the contact holes provided in the adhesive layer 117 and the second planarization layer 118.

Next, referring to FIG. 4G, a second photoresist pattern 194 can be formed on the conductive material layer 150 through a photolithography process where photoresist is applied, exposed to light, and developed. The second photoresist pattern 194 can cover a portion of the conductive material layer 150 corresponding to the first element electrode 141 of the light-emitting element 140 and can expose a portion of the conductive material layer 150 corresponding to the second element electrode 142 of the light-emitting element 140. In addition, the second photoresist pattern 194 can cover portions of the conductive material layer 150 corresponding to the contact holes of the adhesive layer 117 and the second planarization layer 118 and can expose other portions of the conductive material layer 150.

Then, the conductive material layer 150 can be selectively removed using the second photoresist pattern 194 as an etching mask, thereby forming a conductive material pattern 150a and exposing the second element electrode 142 and the second planarization layer 118.

Next, referring to FIG. 4H, the second photoresist pattern 194 can be partially removed through an ashing process, thereby forming a second photoresist pattern 194a having the reduced thickness and width. Accordingly, the conductive material pattern 150a corresponding to the first element electrode 141 can be exposed.

Next, the conductive material pattern 150a can be selectively removed using the second photoresist pattern 194 as an etching mask, thereby forming the first electrode 152, the second connection electrode 154, and the contact electrode 156, and as shown in FIG. 4I, the second photoresist pattern 194a can be stripped and removed. In this case, the first electrode 152 can be in contact with the auxiliary electrode 145 exposed to correspond to the side surface of the semiconductor layer 143 and may not be formed on the top surface of the semiconductor layer 143.

Next, referring to FIG. 4J, the third planarization layer 119 can be formed on the first electrode 152, the second connection electrode 154, and the contact electrode 156 by applying an organic insulating material substantially all over the substrate 110, and can be patterned through a photolithography process, thereby forming the contact holes that expose the second connection electrode 154 and the contact electrode 156. In this case, the third planarization layer 119 can cover the light-emitting element 140 and the first electrode 152.

Then, the third planarization layer 119 can be partially removed through an ashing process. Accordingly, the thickness of the third planarization layer 119 can be decreased, thereby exposing the second element electrode 142 of the light-emitting element 140. In this case, a width of the third planarization layer 119 can also be decreased through the ashing process together with the thickness of the third planarization layer 119.

Next, referring to FIG. 4K, the second electrode 162 can be formed on the third planarization layer 119 by depositing a conductive material and then patterning it through a photolithography process. The second electrode 162 can cover the light-emitting element 140 and can be in contact with the exposed second element electrode 142 of the light-emitting element 140. In addition, the second electrode 162 can also be in contact with the second connection electrode 154 through the contact hole of the third planarization layer 119.

The second electrode 162 can be configured to overlap the first element electrode 141 as well as the second element electrode 142 considering the margin according to the process deviation. At this time, in the process of forming and then removing the second planarization layer 118 and the first and second photoresist patterns 192 and 194 on the first element electrode 141, if the organic material is not completely removed, the distance between the first electrode 152 connected to the first element electrode 141 and the second electrode 162 connected to the second element electrode 142 can be shorter. Accordingly, if the auxiliary electrode 145 is not provided, the second electrode 162 can be in contact with the first electrode 152, and the first element electrode 141 and the second element electrode 142 of the light-emitting element can be electrically short-circuited.

However, in the embodiment of the present disclosure, the first element electrode 141 can be covered with the auxiliary electrode 145 and the second protection layer 146, and the first electrode 152 can be in contact with the auxiliary electrode 145 provided on the side surface of the semiconductor layer 143, so that the distance between the first electrode 152 and the second electrode 162 can increase compared to the case in which the auxiliary electrode 145 is not provided. Accordingly, it is possible to prevent the electrical short-circuiting between the first element electrode 141 and the second element electrode 142 of the light-emitting element 140.

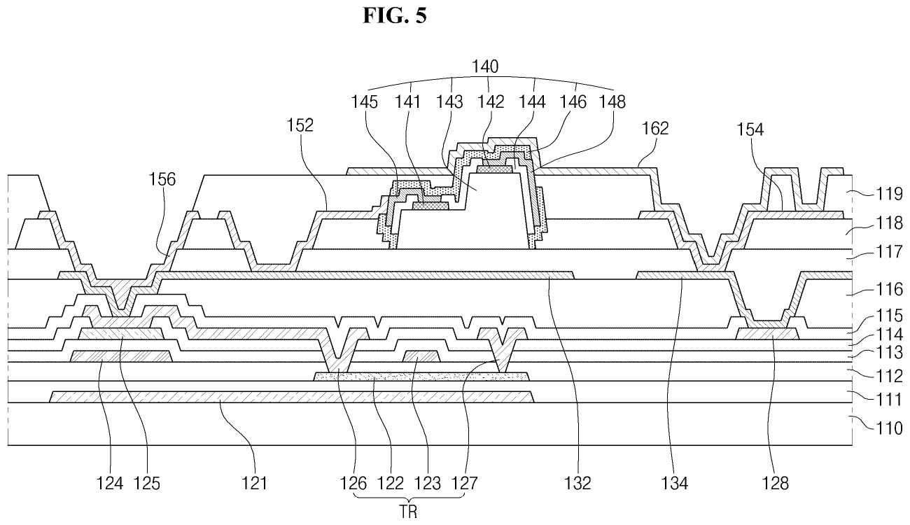

Meanwhile, the light-emitting element 140 can further include an auxiliary electrode connected to the second element electrode 142. Such a light-emitting diode display device according to another embodiment of the present disclosure will be described with reference to FIG. 5.

FIG. 5 is a schematic cross-sectional view of a light-emitting diode display device (or light-emitting element display device) according to another embodiment of the present disclosure. The light-emitting diode display device according to another embodiment of the present disclosure has substantially the same configuration as that of the previous embodiment, except for the auxiliary electrode. The same parts as those of the previous embodiment are designated by the same or similar reference signs, and explanation for the same parts can be shortened or omitted.

Referring to FIG. 5, in the light-emitting diode display device according to another embodiment of the present disclosure, the light-emitting element 140 can be transferred onto the adhesive layer 117. The light-emitting element 140 can include the first element electrode 141, the second element electrode 142, the semiconductor layer 143, the first protection layer 144, the first auxiliary electrode 145, the second protection layer 146, and a second auxiliary electrode 148.

The first auxiliary electrode 145 can be in contact with the first element electrode 141, and the second auxiliary electrode 148 can be in contact with the second element electrode 142. Each of the first and second auxiliary electrodes 145 and 148 can be provided to correspond to the top and side surfaces of the semiconductor layer 143.

The second protection layer 146 can be provided on the first and second auxiliary electrodes 145 and 148. The second protection layer 146 can cover the first and second auxiliary electrodes 145 and 148 corresponding to the top surface of the semiconductor layer 143 and can expose the first and second auxiliary electrodes 145 and 148 corresponding to the side surface of the semiconductor layer 143.

Next, the second planarization layer 118 can be provided on the adhesive layer 117 provided with the light-emitting element 140 thereon. The second planarization layer 118 can expose the first and second auxiliary electrodes 145 and 148.

Then, the first electrode 152, the second connection electrode 154, and the contact electrode 156 can be provided on the second planarization layer 118. The first electrode 152 can be in contact with the exposed first auxiliary electrode 145 corresponding to the side surface of the semiconductor layer 143 and may not be formed on the auxiliary electrode 145 corresponding to the top surface of the semiconductor layer 143.

The third planarization layer 119 can be provided on the first electrode 152, the second connection electrode 154, and the contact electrode 156. The third planarization layer 119 can cover the first electrode 152, the first element electrode 141 of the light-emitting element 140, and the first auxiliary electrode 145 of the light-emitting element 140 and can expose a part of the second auxiliary electrode 148 of the light-emitting element 140. In this case, the third planarization layer 119 can expose the second auxiliary electrode 148 corresponding to the side surface of the semiconductor layer 143.

Next, the second electrode 162 can be provided on the third planarization layer 119. The second electrode 162 can cover the light-emitting element 140 and can be in contact with the exposed second auxiliary electrode 148 corresponding to the side surface of the semiconductor layer 143.

As such, in the light-emitting diode display device according to another embodiment of the present disclosure, by providing the first and second auxiliary electrodes 145 and 148 and connecting the first and second auxiliary electrodes 145 and 148 with the first electrode 152 and the second electrode 162 on the different side surfaces of the light-emitting element 140, the distance between the first electrode 152 and the second electrode 162 can increase compared to a light-emitting diode display device including a light-emitting element without an auxiliary electrode. Accordingly, it is possible to prevent an electrical short-circuiting problem between the first and second element electrodes 141 and 142 of the light-emitting element 140 due to the contact between the first and second electrodes 152 and 162.

The first auxiliary electrode 145 can have a first area which is exposed by the second protection layer, the second auxiliary electrode 148 can have a second area which is exposed by the second protection layer 146, and the second area is higher than the first area.

Various aspects of the present disclosure can be discussed as follows.

Aspects of the present disclosure provide a light-emitting diode which can comprise a semiconductor layer; a first element electrode on the semiconductor layer; a second element electrode on the semiconductor layer; a first auxiliary electrode connected to the first element electrode and located on one side surface of the light-emitting diode; a first protection layer on the first element electrode and the second element electrode; and a second protection layer on the first auxiliary electrode and the first protection layer.

A position of the second element electrode can be higher than a position of the first element electrode.

The first protection layer can expose the first element electrode and the second element electrode, and wherein the first protection layer extends from a top surface of the first element electrode to a side surface of the semiconductor layer.

The second protection layer can be in contact with the first auxiliary electrode and exposes the first auxiliary electrode located on the one side surface of the light-emitting diode.

The first auxiliary electrode can be in contact with a top surface of the first element electrode and extends from the top surface of the first element electrode to the one side surface of the light-emitting diode, and wherein the first auxiliary electrode covers the first protection layer on the one side surface of the light-emitting diode.

The light-emitting diode can further comprise a second auxiliary electrode located on another side surface of the light-emitting element and the another side surface is separated from the one side surface.

The second auxiliary electrode can be in contact with a top surface of the second element electrode and extends from the second element electrode to the another side surface of the light-emitting diode, and wherein on the another side surface of the light-emitting diode, the second auxiliary electrode covers the first protection layer, and the second protection layer exposes the second auxiliary electrode located on the another side surface of the light-emitting diode.

The first auxiliary electrode can have a first area which is exposed by the second protection layer, the second auxiliary electrode has a second area which is exposed by the second protection layer, and the second area is higher than the first area.

The first protection layer can extend from a top surface of the first element electrode to a side surface of the semiconductor layer, and wherein the second protection layer exposes the first auxiliary electrode located on the side surface of the semiconductor layer.

Aspects of the present disclosure provide a light-emitting element display device which can comprise a substrate; a light-emitting element disposed on the substrate, the light-emitting element comprising a first element electrode, a second element electrode and an auxiliary electrode, the first element electrode and the second element electrode being spaced apart from each other, and the auxiliary electrode being located on at least one side of the light-emitting element; a first electrode connected to the first element electrode; and a second electrode on the first electrode and connected to the second element electrode, wherein at least one of the first electrode and the second electrode are connected to at least one of the first element electrode and the second element electrode by the auxiliary electrode.

The light-emitting element display device can further comprise a thin film transistor disposed on the substrate; and a reflection electrode disposed on the thin film transistor, and the reflection electrode connected to the thin film transistor and the first electrode.

The light-emitting element display device can further comprise a power line disposed on the substrate and spaced apart from the thin film transistor, wherein the power line is the same layer as a source electrode and a drain electrode of the thin film transistor.

The light-emitting element display device can further comprise a first connection electrode disposed on the thin film transistor and the power line, wherein the first connection electrode is connected to the power line.

The light-emitting element display device can further comprise a second connection electrode on the first connection electrode and in contact with the first connection electrode, wherein the second electrode is connected to the second connection electrode.

The light-emitting element display device can further comprise an adhesive layer disposed on the reflection electrode; a second planarization layer on which the first electrode is disposed; and a third planarization layer covering the first electrode, wherein the second electrode is located on the third planarization layer, wherein the second electrode is in contact with the second connection electrode by a contact hole disposed in the third planarization layer.

The light-emitting element display device can further comprise a first capacitor electrode; and a second capacitor electrode on the first capacitor electrode, wherein the second capacitor electrode is electrically connected to the thin film transistor.

The first electrode can be in contact with a first auxiliary electrode of the auxiliary electrode of the auxiliary electrode located on one side of the light-emitting element, and wherein the second electrode is in contact with a second auxiliary electrode of the auxiliary electrode located on another side of the light-emitting element.

The second auxiliary electrode can be in contact with a top surface of the second element electrode and extends from the second element electrode to the another side of the light-emitting element, and wherein on the another side of the light-emitting element, the second auxiliary electrode covers the first protection layer, and the second protection layer exposes the second auxiliary electrode located on the another side of the light-emitting element.

The first connection electrode and the reflection electrode can be in a same layer and formed of a same material.

The first element electrode can be on the second planarization layer.

Aspects of the present disclosure provide a light-emitting element display device which can comprise a plurality of sub-pixels, and each of the plurality of sub-pixels comprises a substrate; a light-emitting element disposed on the substrate, wherein the light-emitting element comprises an auxiliary electrode, and the auxiliary electrode is located on at least one of two side surfaces of the light-emitting element; a first electrode; and a second electrode on the first electrode, wherein at least one of the first electrode and the second electrode is connected to the light-emitting element by the auxiliary electrode.

The light-emitting element can further comprise a first element electrode and a second element electrode spaced apart from each other, and a position of the second element electrode is higher than a position of the first element electrode, wherein the first electrode is connected to the first element electrode and the second electrode is connected to the second element electrode.

In the light-emitting element display device of the present disclosure, by providing at least one auxiliary electrode on the side surface of the light-emitting element and connecting the auxiliary electrode with an electrode of the array substrate, it is possible to prevent an electrical short-circuiting between the electrodes of the light-emitting element.

The light-emitting element can be transferred on the array substrate after being self-assembled on the assembly substrate and then forming the auxiliary electrode, so that the manufacturing process of the light-emitting element display device can be optimized and the energy consumption can be reduced.

It will be apparent to those skilled in the art that various modifications and variations can be made in the light-emitting element display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A light-emitting diode comprising:
a semiconductor layer;
a first element electrode on the semiconductor layer;
a second element electrode on the semiconductor layer;
a first auxiliary electrode connected to the first element electrode and located on one side surface of the light-emitting diode;
a first protection layer on the first element electrode and the second element electrode; and
a second protection layer on the first auxiliary electrode and the first protection layer.

2. The light-emitting diode according to claim 1, wherein a position of the second element electrode is higher than a position of the first element electrode.

3. The light-emitting diode according to claim 1, wherein the first protection layer exposes the first element electrode and the second element electrode, and
wherein the first protection layer extends from a top surface of the first element electrode to a side surface of the semiconductor layer.

4. The light-emitting diode according to claim 1, wherein the second protection layer is in contact with the first auxiliary electrode and exposes the first auxiliary electrode located on the one side surface of the light-emitting diode.

5. The light-emitting diode according to claim 1, wherein the first auxiliary electrode is in contact with a top surface of the first element electrode and extends from the top surface of the first element electrode to the one side surface of the light-emitting diode, and
wherein the first auxiliary electrode covers the first protection layer on the one side surface of the light-emitting diode.

6. The light-emitting diode according to claim 1, further comprising:
a second auxiliary electrode located on another side surface of the light-emitting diode,
wherein the another side surface of the light-emitting diode is separated from the one side surface of the light-emitting diode.

7. The light-emitting diode according to claim 6, wherein the second auxiliary electrode is in contact with a top surface of the second element electrode and extends from the second element electrode to the another side surface of the light-emitting diode, and
wherein on the another side surface of the light-emitting diode, the second auxiliary electrode covers the first protection layer, and the second protection layer exposes the second auxiliary electrode located on the another side surface of the light-emitting diode.

8. The light-emitting diode according to claim 6, wherein the first auxiliary electrode has a first area which is exposed by the second protection layer, the second auxiliary electrode has a second area which is exposed by the second protection layer, and the second area of the second auxiliary electrode is higher than the first area of the first auxiliary electrode.

9. The light-emitting diode according to claim 1, wherein the first protection layer extends from a top surface of the first element electrode to a side surface of the semiconductor layer, and
wherein the second protection layer exposes the first auxiliary electrode located on the side surface of the semiconductor layer.

10. A light-emitting element display device comprising:
a substrate;
a light-emitting element disposed on the substrate, the light-emitting element comprising a first element electrode, a second element electrode and an auxiliary electrode, the first element electrode and the second element electrode being spaced apart from each other, and the auxiliary electrode being located on at least one side of the light-emitting element;
a first electrode connected to the first element electrode; and
a second electrode on the first electrode and connected to the second element electrode,
wherein at least one of the first electrode and the second electrode are connected to at least one of the first element electrode and the second element electrode by the auxiliary electrode.

11. The light-emitting element display device according to claim 10, further comprising:
a thin film transistor disposed on the substrate; and
a reflection electrode disposed on the thin film transistor, and the reflection electrode connected to the thin film transistor and the first electrode.

12. The light-emitting element display device according to claim 11, further comprising:
a power line disposed on the substrate and spaced apart from the thin film transistor,
wherein the power line is a same layer as a source electrode and a drain electrode of the thin film transistor.

13. The light-emitting element display device according to claim 12, further comprising:
a first connection electrode disposed on the thin film transistor and the power line,
wherein the first connection electrode is connected to the power line.

14. The light-emitting element display device according to claim 13, further comprising:
a second connection electrode on the first connection electrode and in contact with the first connection electrode,
wherein the second electrode is connected to the second connection electrode.

15. The light-emitting element display device according to claim 14, further comprising:
an adhesive layer disposed on the reflection electrode;
a second planarization layer on which the first electrode is disposed; and
a third planarization layer covering the first electrode,
wherein the second electrode is located on the third planarization layer, and
wherein the second electrode is in contact with the second connection electrode by a contact hole disposed in the third planarization layer.

16. The light-emitting element display device according to claim 11, further comprising:
a first capacitor electrode; and
a second capacitor electrode on the first capacitor electrode,
wherein the second capacitor electrode is electrically connected to the thin film transistor.

17. The light-emitting element display device according to claim 10, wherein the first electrode is in contact with a first auxiliary electrode of the auxiliary electrode located on one side of the light-emitting element, and
wherein the second electrode is in contact with a second auxiliary electrode of the auxiliary electrode located on another side of the light-emitting element.

18. The light-emitting element display device according to claim 17, wherein the second auxiliary electrode is in contact with a top surface of the second element electrode and extends from the second element electrode to the another side of the light-emitting element, and
wherein on the another side of the light-emitting element, the second auxiliary electrode covers a first protection layer, and a second protection layer exposes the second auxiliary electrode located on the another side of the light-emitting element.

19. The light-emitting element display device according to claim 13, wherein the first connection electrode and the reflection electrode are in a same layer and include a same material.

20. The light-emitting element display device according to claim 15, wherein the first element electrode is on the second planarization layer.
